(19) United States
(12) Patent Application Publication
(10) Pub. No.: US 2026/0354102 A1
(43) Pub. Date: Nov. 5, 2026

(54) APPARATUS AND METHOD FOR REAL-TIME MONITORING A SUBSTRATE CHUCKING STATUS

(71) Applicant: ASM IP Holding B.V., Almere (NL)

(72) Inventors: Sergei Golovkov, Tokyo (JP); HyeanGi Oh, Gumi-si (KR); Gopu Krishna, Chandler, AZ (US)

(21) Appl. No.: 19/662,623

(22) Filed: Apr. 29, 2026

Related U.S. Application Data
(60) Provisional application No. 63/798,781, filed on May 2, 2025.

(51) Int. Cl. H10P 72/72; H01J 37/32; H10P 72/00

(52) U.S. Cl. CPC H10P 72/722; H01J 37/32174; H01J 37/32183; H01J 37/32715; H01J 37/32935; H10P 72/0604

(57) ABSTRACT

A system and method for determining a real-time chucking status of a substrate on an electrostatic chuck is disclosed. Specifically, the system and method involve measuring a capacitance to determine whether the substrate is chucked or unchucked. Components of the system may comprise a matching unit, a bandpass filter, a high voltage power supply, a RF filter, an electrostatic chuck, and a gas distribution device.

### CROSS-REFERENCE TO RELATED APPLICATIONS

This application claims priority to U.S. Provisional Patent Application Ser. No. 63/798,781 filed May 2, 2025 and titled APPARATUS AND METHOD FOR REAL-TIME MONITORING A SUBSTRATE CHUCKING STATUS, the disclosure of which is hereby incorporated by reference in its entirety.

### FIELD OF INVENTION

The current invention is in the field of semiconductor manufacturing. Specifically, embodiments of the current invention relate to systems used in the processing of semiconductor films.

### BACKGROUND OF THE DISCLOSURE

Systems for processing semiconductor films include a substrate holder, on which a substrate sits during the processing. The substrate holder may comprise an electrostatic chuck (ESC). The electrostatic chuck may comprise an electrode through which a current is applied from a voltage source, which results in the substrate flattening onto the substrate holder. This may be due to the fact that the current applied has one polarity (positive or negative), which is attracted to the other polarity within the substrate itself. The status of the substrate being flatten onto the substrate holder is called chucked or clamped.

When the substrate is chucked or clamped, processing the substrate in a uniform manner is possible. With uniformity, a film of level thickness may be formed. If processing occurs while the substrate is not chucked or clamped, the substrate may be bowed in a concave or a convex shape. When the substrate is processed while being in a concave or a convex shape, a film formed may be uneven. Such a non-uniformity may affect eventual performance of a device formed from that substrate. Knowledge of whether a substrate is chucked or not may help increase throughput and prevent loss of processed substrates.

Electrostatic chucks may be either monopolar or bipolar. Monopolar electrostatic chucks have a single electrode with a single voltage source applying a current to the electrode. Bipolar electrostatic chucks have two electrodes and two voltage sources. The two electrodes of the bipolar electrostatic chucks will have two different polarities of current applied (positive and negative).

Determining a chucking status may be done by determining a phase shift, as described in U.S. Non-Provisional patent application Ser. No. 18/926,695, filed on Oct. 25, 2024, entitled “SUBSTRATE PROCESSING SYSTEM WITH CAPABILITIES FOR DETECTING WHETHER A WAFER IS DECHUCKED AND A METHOD THEREOF,” and hereby incorporated by reference. A capacitively-coupled electrostatic probe may be used to determine the chucking status, as described in U.S. Pat. No. 8,780,522, filed on Jul. 7, 2009, entitled “CAPACITIVELY-COUPLED ELECTROSTATIC (CCE) PROBE ARRANGEMENT FOR DETECTING DECHUCKING IN A PLASMA PROCESS CHAMBER AND METHODS THEREOF,” and hereby incorporated by reference.

Bipolar electrostatic chucks have the ability to determine a chucking status regardless of whether a plasma is being generated. However, monopolar electrostatic chucks can only determine a chucking status when a plasma is generated. As a result, a system and method for determining a real-time chucking status regardless of the status of the plasma generation is desired.

FIG. 1 illustrates a prior art plasma processing system 100 for determining a chucking status with a monopolar electrostatic chuck. The plasma processing system 100 comprises: a matching unit 110; a band pass filter 120; a electrostatic chuck power supply with a capacitance measurement circuit 130; a RF filter 140; a susceptor with at least two capacitors 150; and a plasma switch 160. The band pass filter 120 protects components of the system from a power loss of applied RF power on the showerhead.

When the plasma switch 160 is on, the plasma processing system 100 is able to measure a chucking status through a difference of readings in the two capacitors within the susceptor 150. A shift in the impedance when the substrate is on the susceptor versus when the substrate is off the susceptor is measured to determine the chucking status. This may be done by syncing the capacitance measurement with an RF power on timing or by a time average of the overall capacitance during a plasma on state and a plasma off state.

However, if the plasma switch 160 is off, the plasma processing system 100 is unable to make any determination of a chucking state of a substrate. As a result, it is desired to have a system that is able to determine a chucking status regardless of whether a plasma switch is on or off.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

In at least one embodiment of the invention, a processing system for a semiconductor substrate is disclosed. The processing system comprises: a reaction chamber; a gas distribution device disposed in the reaction chamber, the gas distribution device comprising a first electrode and being configured to distribute a gas onto a substrate and generate a first capacitance detection frequency signal; an electrostatic chuck disposed in the reaction chamber and configured to hold the substrate for processing; a second electrode disposed in the electrostatic chuck and configured to generate a second capacitance detection frequency signal; a high voltage power source disposed outside the reaction chamber, the high voltage power source being configured to monitor the first capacitance detection frequency signal and the second capacitance detection frequency signal to determine a frequency phase shift and calculate a capacitance from the frequency phase shift, wherein the high voltage power source is configured to provide a first power signal to the second electrode; and a RF filter configured to filter the power signal to the second electrode and configured to provide the second capacitance detection frequency signal to the high voltage power source; a bandpass filter configured to provide the first capacitance detection frequency signal to the high voltage power source; wherein the capacitance from the frequency phase shift indicates a real-time chucking status of the substrate.

In at least one embodiment of the invention, a method of determining a chucking status of a substrate is disclosed. The method comprises: providing a substrate in a processing system, the processing system comprising: a reaction chamber; a gas distribution device disposed in the reaction chamber, the gas distribution device comprising a first electrode and being configured to distribute a gas onto a substrate and generate a first capacitance detection frequency signal; an electrostatic chuck disposed in the reaction chamber and configured to hold the substrate for processing; a second electrode disposed in the electrostatic chuck and configured to generate a second capacitance detection frequency signal; a high voltage power source disposed outside the reaction chamber, the high voltage power source being configured to monitor the first capacitance detection frequency signal and the second capacitance detection frequency signal to determine a frequency phase shift and calculate a capacitance from the frequency phase shift, wherein the high voltage power source is configured to provide a first power signal to the second electrode; and a RF filter configured to filter the power signal to the second electrode and configured to provide the second capacitance detection frequency signal to the high voltage power source; a bandpass filter configured to provide the first capacitance detection frequency signal to the high voltage power source; pulsing the first power signal from the high voltage power source; and monitoring the capacitance from the frequency phase shift for indicating a real-time chucking status of the substrate.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a circuitry diagram of a prior art system.

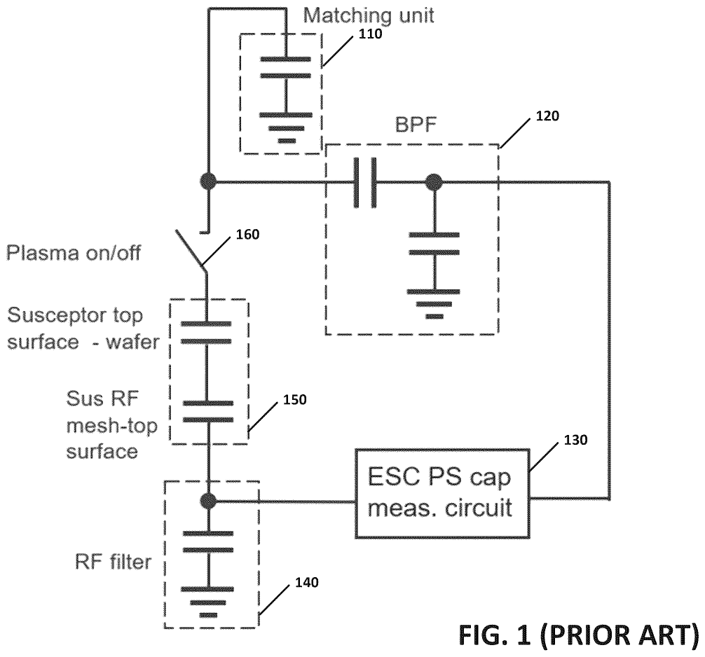

FIG. 2 is a schematic of a semiconductor manufacturing system in accordance with at least one embodiment of the invention.

FIG. 3 is a signal diagram in accordance with at least one embodiment of the invention.

FIG. 4 is a capacitance signal diagram in accordance with at least one embodiment of the invention.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

In this disclosure, “gas” may include material that is a gas at normal temperature and pressure, a vaporized solid and/or a vaporized liquid, and may be constituted by a single gas or a mixture of gases, depending on the context. A gas introduced without passing through a gas supply unit, such as a shower plate, or the like, may be used for, e.g., sealing the reaction space, and may include a seal gas, such as a rare or other inert gas. The term inert gas, carrier gas, and dilution gas refer to a gas that does not take part in a chemical reaction to an appreciable extent and/or a gas that can excite a precursor when plasma power is applied.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

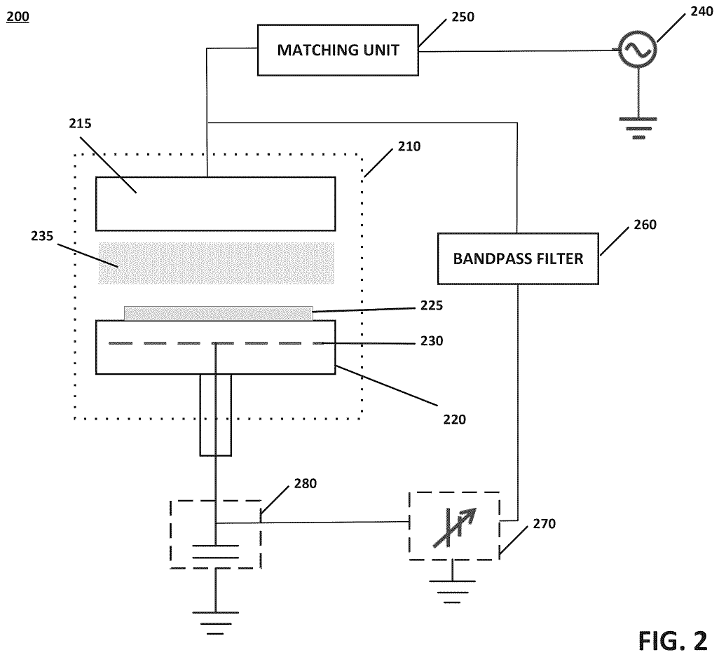

FIG. 2 illustrates a plasma processing system 200 in accordance with at least one embodiment of the invention. The plasma processing system 200 may comprise a reaction chamber 210, which includes a gas distributor 215, an electrostatic chuck 220 configured to hold a substrate 225, and an electrode 230 disposed within the electrostatic chuck 220. The gas distributor 215 may be configured to flow a gas evenly onto the substrate 225. In addition, the gas distributor 215 may be configured to act as an electrode and may generate a first capacitance detection frequency signal. The electrode 230 may generate a second capacitance detection frequency signal.

A plasma 235 may be generated from the gas within the reaction chamber 210 by applying a power generated from a RF generator 240. The plasma 235 then may be used to process the substrate 225 through a plasma enhanced atomic layer deposition (PEALD), a plasma enhanced chemical vapor deposition (PECVD), a physical vapor deposition (PVD), a sputtering, or an etching process.

The plasma processing system 200 also may comprise: a RF signal generator 240; a matching unit 250; a bandpass filter 260; a high voltage power source with a capacitive monitoring function 270, and a RF filter 280. As stated previously, the RF generator 240 generates an RF power for forming a plasma from the gas flowed in the reaction chamber 210. The matching unit 250 may be configured to adjust an impedance of the reaction chamber 210 for the generated RF power to be more effective in wafer processing.

The bandpass filter 260 may be configured to allow the first capacitance detection frequency signal measurement from the gas distributor 215 to pass through to the high voltage power source 270. The distance between the bandpass filter 260 and the gas distributor 215 may be reduced to match the supply frequency wavelength in order to reduce a power loss in a connection between the gas distributor 215 and the bandpass filter 260.

A capacitance measurement determined at the high voltage power source 270 can indicate a chucking status of the substrate 225. The capacitance measurement may be determined by detecting a frequency phase shift between the first capacitance detection frequency signal and the second capacitance detection frequency signal.

The capacitance measurement may be a function as shown by the following equation, wherein C is the capacitance in Farads, & is the absolute permittivity of the dielectric, A is the area of plate overlap in square meters, and d is the distance between plates in meters.

$$C = \frac{ε A}{d} \qquad [ 1 ]$$

A capacitance of a chucked substrate 225 may differ from that of an unchucked substrate because the distance between the substrate and a top surface of the electrostatic chuck 220.

The high voltage power source 270 then may adjust a HRF power provided via the RF filter 280 to electrode 230 in the electrostatic chuck 220. The RF filter 280 may isolate the high voltage power source 270 from the HRF power from the RF generator 240.

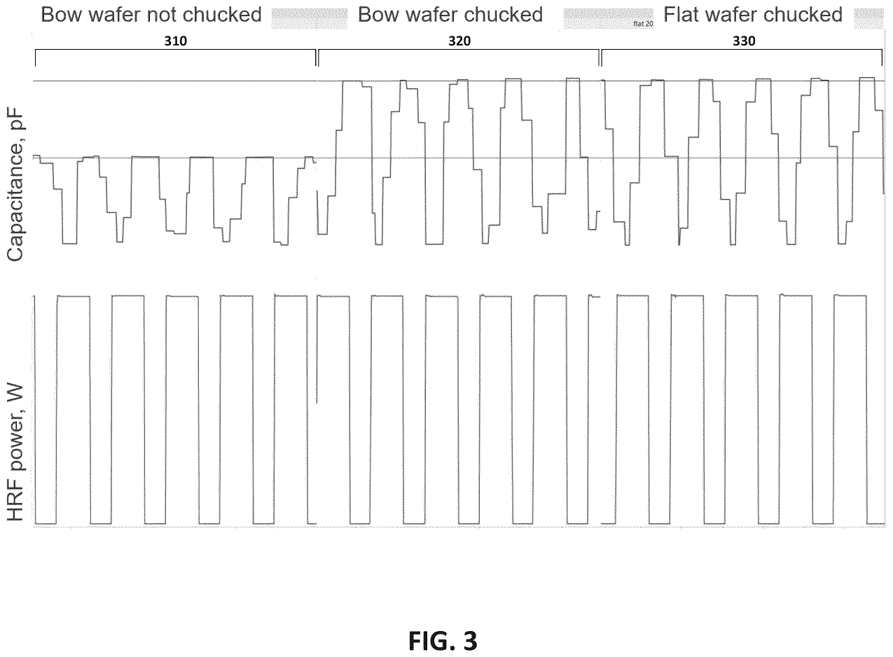

FIG. 3 illustrates signal waveform diagram of a substrate or wafer in accordance with at least one embodiment of the invention. Depending on a status of the HRF power generated by the high voltage power source 270, a measured capacitance may differ depending on whether the substrate 225 is bowed or flat, chucked or not chucked.

When a bowed substrate is not chucked, an unchucked bowed substrate capacitance signal waveform 310 may result. The unchucked bowed substrate capacitance signal waveform 310 may only toggle between a low signal and a middle baseline signal when a HRF power is switched between an on and off state.

When the bowed substrate is chucked, a chucked bowed substrate capacitance signal waveform 320 may result. The chucked bowed substrate capacitance signal waveform 320 may toggle between a low signal and a high signal when a HRF power is switched between an on and off state.

When a flat substrate is chucked, a chucked flat substrate capacitance signal waveform 330 may result. The chucked bowed substrate capacitance signal waveform 330 may toggle between a low signal and a high signal when a HRF power is switched between an on and off state. There may not be much of a difference in the chucked bowed substrate capacitance signal waveform 320 and the chucked bowed substrate capacitance signal waveform 330 because both wafers are flat.

The chucking status is determined by comparing the chucked substrate capacitance signal waveform to the flat substrate capacitance signal waveform 330. If they match, the system will continue to operate. However, if they do not match, the system will signal an alert stating that the substrate is not chucked.

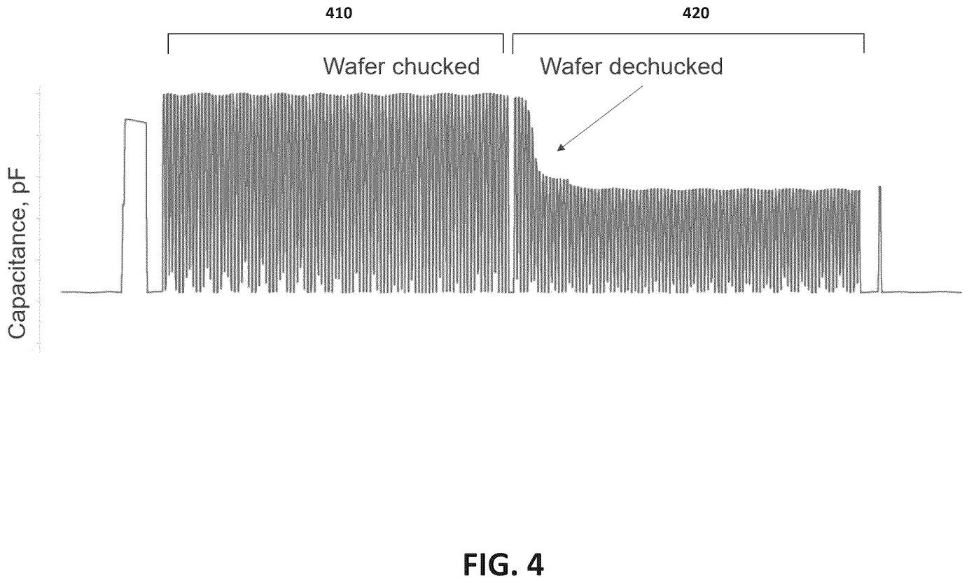

FIG. 4 illustrates signal waveform diagram of a substrate or wafer in accordance with at least one embodiment of the invention. When the substrate 225 is chucked, a capacitance signal waveform 410 may result, where the capacitance varies between a low and a high signal. When the substrate 225 is unchucked, a capacitance signal waveform 420 may result, where the capacitance varies between a low and a middle signal. As shown in the equation [I], the area A of the overlap between the substrate and the susceptor decreases when the substrate is unchucked; thus, as a result, the overall capacitance C may decrease.

The decrease in capacitance signal may indicate that the substrate is unchucked. With this knowledge, processing of the substrate may be paused to allow for the substrate to be flattened. A properly flattened substrate may then result in a proper film to be formed on the substrate.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

We claim:

1. A processing system for a semiconductor substrate, wherein the processing system comprises:
a reaction chamber;
a gas distribution device disposed in the reaction chamber, the gas distribution device comprising a first electrode and being configured to distribute a gas onto a substrate and generate a first capacitance detection frequency signal;
an electrostatic chuck disposed in the reaction chamber and configured to hold the substrate for processing;
a second electrode disposed in the electrostatic chuck and configured to generate a second capacitance detection frequency signal;
a high voltage power source disposed outside the reaction chamber, the high voltage power source being configured to monitor the first capacitance detection frequency signal and the second capacitance detection frequency signal to determine a frequency phase shift and calculate a capacitance from the frequency phase shift, wherein the high voltage power source is configured to provide a first power signal to the second electrode; and
a RF filter configured to filter the power signal to the second electrode and configured to provide the second capacitance detection frequency signal to the high voltage power source;
a bandpass filter configured to provide the first capacitance detection frequency signal to the high voltage power source;
wherein the capacitance from the frequency phase shift indicates a real-time chucking status of the substrate.

2. The processing system of claim 1, further comprising a matching unit configured to adjust an impedance of the reaction chamber.

3. The processing system of claim 2, further comprising a RF generator coupled to the matching unit, wherein the RF generator is configured to provide a second power signal to the first electrode via the matching unit.

4. The processing system of claim 1, wherein the RF filter is configured to tune an impedance of the RF filter.

5. The processing system of claim 1, wherein a plasma is generated between the gas distribution device and the electrostatic chuck.

6. The processing system of claim 1, wherein the real-time chucking status indicates whether the substrate is chucked or unchucked.

7. A method of determining a chucking status of a substrate, the method comprising:
providing a substrate in a processing system, the processing system comprising:
a reaction chamber;
a gas distribution device disposed in the reaction chamber, the gas distribution device comprising a first electrode and being configured to distribute a gas onto a substrate and generate a first capacitance detection frequency signal;
an electrostatic chuck disposed in the reaction chamber and configured to hold the substrate for processing;
a second electrode disposed in the electrostatic chuck and configured to generate a second capacitance detection frequency signal;
a high voltage power source disposed outside the reaction chamber, the high voltage power source being configured to monitor the first capacitance detection frequency signal and the second capacitance detection frequency signal to determine a frequency phase shift and calculate a capacitance from the frequency phase shift, wherein the high voltage power source is configured to provide a first power signal to the second electrode; and
a RF filter configured to filter the power signal to the second electrode and configured to provide the second capacitance detection frequency signal to the high voltage power source;
a bandpass filter configured to provide the first capacitance detection frequency signal to the high voltage power source;
pulsing the first power signal from the high voltage power source; and
monitoring the capacitance from the frequency phase shift for indicating a real-time chucking status of the substrate.

8. The method of claim 7, wherein the processing system further comprises a matching unit configured to adjust an impedance of the reaction chamber.

9. The method of claim 7, wherein the processing system further comprises a RF generator coupled to the matching unit, wherein the RF generator is configured to provide a second power signal to the first electrode via the matching unit.

10. The method of claim 7, wherein the RF filter is configured to tune an impedance of the RF filter.

11. The method of claim 7, wherein a plasma is generated between the gas distribution device and the electrostatic chuck.

12. The method of claim 7, wherein the real-time chucking status indicates whether the substrate is chucked or unchucked.
